(19) United States
(12) Patent Application Publication
(10) Pub. No.: US 2008/0160731 A1
(43) Pub. Date: Jul. 3, 2008

(54) METHOD FOR FABRICATING CMOS IMAGE SENSOR

(75) Inventor: Joung Ho LEE, Seoul (KR)

Correspondence Address: LOWE HAUPTMAN HAM & BERNER, LLP, 1700 DIAGONAL ROAD, SUITE 300, ALEXANDRIA, VA, 22314, US

(73) Assignee: Dongbu HiTek Co., Ltd., Seoul (KR)

(21) Appl. No.: 11/778,475

(22) Filed: Jul. 16, 2007

(30) Foreign Application Priority Data
Dec. 27, 2006 (KR) 10-2006-00135684

(51) Int. Cl. H01L 21/265

(52) U.S. Cl. 438/527; 257/E21.334

(57) ABSTRACT

A method for fabricating a Complementary Metal Oxide Semiconductor (CMOS) image sensor includes implanting first conductive type dopants into a semiconductor substrate and forming a photodiode region in a surface of the semiconductor substrate, performing spike annealing to the semiconductor substrate having the photodiode region formed thereon, to thereby suppress diffusion of the first conductive type dopants and remove an interstitial between lattices, and implanting second conductive type dopants into an upper part of the photo diode region to form a second conductive type diffusion region.

### FIELD OF THE INVENTION

The present invention relates to a method for fabricating an image sensor, and more particularly, to a method for fabricating a CMOS image sensor, for improving the characteristic of an image sensor.

### BACKGROUND OF THE INVENTION

Generally, an image sensor is a semiconductor device for converting an optical image into an electrical signal. Image sensors may be chiefly classified into Charge-Coupled Devices (CCDs) and CMOS Image Sensors (CIS).

The CCD has a plurality of photodiodes (PD) arranged in matrix form and converting an optic signal into an electric signal. The CCD includes a plurality of Vertical Charge Coupled Devices (VCCDs), a Horizontal Charge Coupled Device (HCCD), and a sense amplifier. The VCCDs are formed between the respective photodiodes arranged in matrix form and transfer charges generated in each photodiode in a vertical direction. The HCCD transfers the charges transferred by each VCCD in a horizontal direction. The sense amplifier senses the horizontally transferred charges and generates an electric signal therefrom.

However, the CCD is complex in driving way and is large in power consumption. In addition, the CCD has a disadvantage in that it is complex in fabrication process because it needs a multi-step photo process.

Further, the CCD cannot be miniaturized because of the difficulty in integrating a controller, a signal processor, and an analog-to-digital (A/D) converter in a chip of the CCD.

Recently, attention is being paid to a CMOS image sensor that is a next generation image sensor capable of overcoming the defects of the CCD.

The CMOS image sensor is a device employing a switching way in which MOS transistors corresponding to the number of unit pixels are formed in a semiconductor substrate using a CMOS fabrication technology, thereby sequentially detecting, by the respective MOS transistors, an output from each unit pixel. In the CMOS fabrication technology, a controller and a signal processor are used as peripheral circuits.

That is, in the CMOS image sensor, a photodiode and a MOS transistor are formed within a unit pixel, thereby sequentially detecting an electric signal of each unit pixel in the switching way and realizing an image.

By using the CMOS fabrication technology, the CMOS image sensor has an advantage in that power consumption is low and a fabrication process is simple owing to the less number of photo process steps.

Further, with the help of the integration of a controller, a signal processor, an A/D converter, and the like into a CMOS image sensor chip, the CMOS image sensor has an advantage in that it is easy to miniaturize as a product.

Accordingly, the CMOS image sensor is being widely used in a variety of application fields such as a digital still camera, a digital video camera, etc.

FIGS. 1A to 1E are cross-sectional diagrams illustrating a method for fabricating a CMOS image sensor in accordance with the conventional art.

As shown in FIG. 1A, a low-concentration P⁻-type epitaxial layer 62 is formed in a high-concentration P⁺⁺-type semiconductor substrate 61 using an epitaxial process.

An active region and a device isolation region are defined in the semiconductor substrate 61. A device isolation film 63 is then formed in the device isolation region using Shallow Trench Isolation (STI) process.

Thereafter, a gate insulating film 64 and a conductive layer (e.g., a high-concentration polycrystalline silicon layer) are sequentially deposited on a whole surface of the epitaxial layer 62 including the device isolation film 63. The conductive layer and the gate insulating film 64 are then selectively removed, thereby forming a gate electrode 65.

As shown in FIG. 1B, a first photoresist film 66 is coated above a whole surface of the semiconductor substrate 61 and is patterned to expose each blue, green, and red photodiode region in an exposure and development process.

Subsequently, low-concentration N-type impurity ions are implanted in the epitaxial layer 62 with the patterned first photoresist film 66 as a mask, thereby forming an N⁻-type diffusion region 67 that is the blue, green, and red photodiode region.

When the N⁻-type diffusion region 67 for the photodiode region is formed, ion implantation of phosphorous (P) is implemented. In order to enhance the efficiency of signal transmission, a series of two processes are performed with different ion implantation energy.

In other words, N-type ion implantation for forming the photodiode region is consecutively performed at different energy of 160 KeV and 100 KeV, respectively. Ion implantation with a low energy is performed at an ion implantation angle of about 4 degrees to 10 degrees. Ion implantation with a high energy is performed at an ion implantation angle of zero degree.

As shown in FIG. 1C, the first photoresist film 66 is thoroughly removed. An insulation film is then deposited and etched back above an entire surface of the semiconductor substrate 61. Thus, insulating sidewalls 68 are formed at both side surfaces of the gate electrode 65. After a second photoresist film 69 is coated above an entire surface of the semiconductor substrate 61, it is patterned to cover the photodiode region and expose a source/drain region of each transistor through an exposure and development process.

Next, high-concentration N⁺-type impurity ions are implanted in the exposed source/drain region using the patterned second photoresist film 69 as a mask, thereby forming an N⁺-type diffusion region (a floated diffusion region) 70.

As shown in FIG. 1D, the second photoresist film 69 is removed. After a third photoresist film 71 is coated above an entire surface of the semiconductor substrate 61, it is patterned to expose each photodiode region by an exposure and development process.

P^{o} -type impurity ions (e.g., BF₂⁺) are implanted in the photodiode region including the N-type diffusion region 67, using the patterned third photoresist film 71 as a mask. Thus, a P⁰-type diffusion region 72 is formed on the N-type diffusion region 62.

In this connection, electrons may be generated in a surface of a photodiode due to a defect of the interface between the photodiode and the semiconductor substrate 61. This may cause a movement of the electrons to the photodiode region to thereby generate an undesired signal in the surface. Thus, the P⁰-type diffusion region 72 with many holes formed at its upper surface serves to remove the electrons by allowing the electrons to couple with the holes.

However, a portion of the electrons remains without removing or coupling with holes and thus, causes a dark current thereby deteriorating a product characteristic of the CMOS sensor.

As shown in FIG. 1E, the third photoresist film 71 is removed. The semiconductor substrate 61 is heat-treated, hereby promoting diffusion in each impurity diffusion region.

As a P-type junction layer is formed thicker by P-type ion implantation in order to remove a dark current, there is a reduction in the dark current and a light sensitivity reduces on the light receiving part. Therefore, a product characteristic is dissatisfied. Thus, after ion implantation, P-type dopants should be prevented to the maximum from being diffused into the photodiode region.

However, in the conventional art, there is a limitation in controlling the diffusion of boron (B) having a small mass and fast diffusion. Accordingly, Ion implantation with a low energy makes it difficult to realize a concentration profile in a desired form.

### SUMMARY OF THE INVENTION

It is, therefore, an object of the present invention is to provide a method for fabricating a CMOS image sensor, capable of improving dark current and sensitivity characteristics of a photodiode receiving light.

In accordance with an aspect of the present invention, there is provided a method for fabricating a Complementary Metal Oxide Semiconductor (CMOS) image sensor, which includes:

implanting first conductive type dopants into a semiconductor substrate and forming a photodiode region in a surface of the semiconductor substrate;

performing spike annealing to the semiconductor substrate having the photodiode region formed thereon; and

implanting second conductive type dopants into an upper part of the photo diode region to form a second conductive type diffusion region.

### BRIEF DESCRIPTION OF THE DRAWINGS

The above and other objects and features of the present invention will become apparent from the following description of embodiments given in conjunction with the accompanying drawings, in which:

FIGS. 1A to 1E are process cross-sectional views illustrating a method for fabricating a CMOS image sensor in accordance with the conventional art; and

FIGS. 2A to 2E are process cross-sectional views illustrating a method for fabricating a CMOS image sensor in accordance with the present invention.

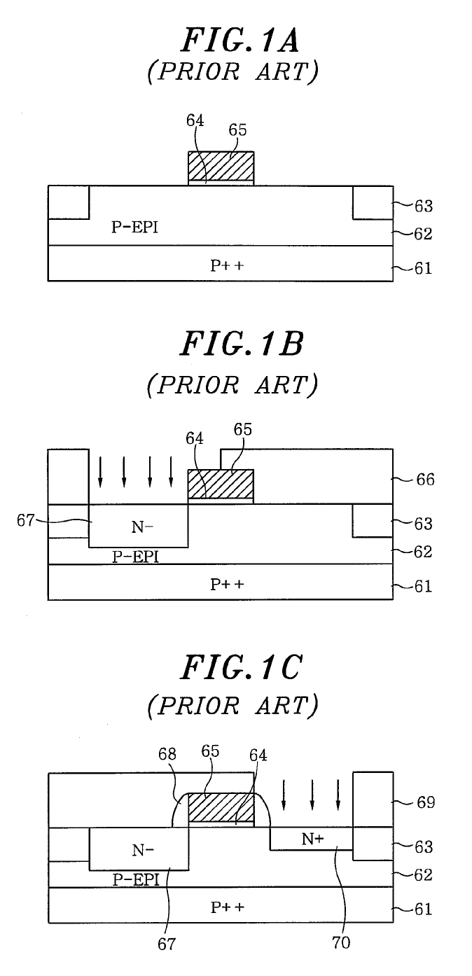

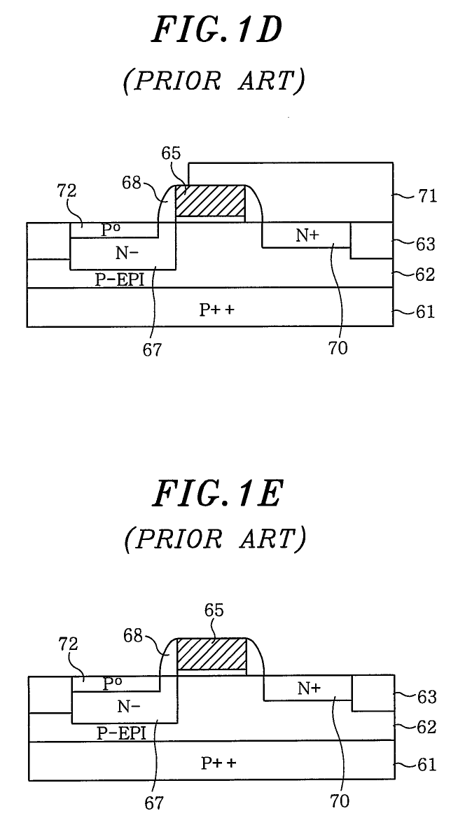

### DETAILED DESCRIPTION OF THE EMBODIMENTS

Hereinafter, exemplary embodiments in accordance with the present invention will be described in detail with the accompanying drawings.

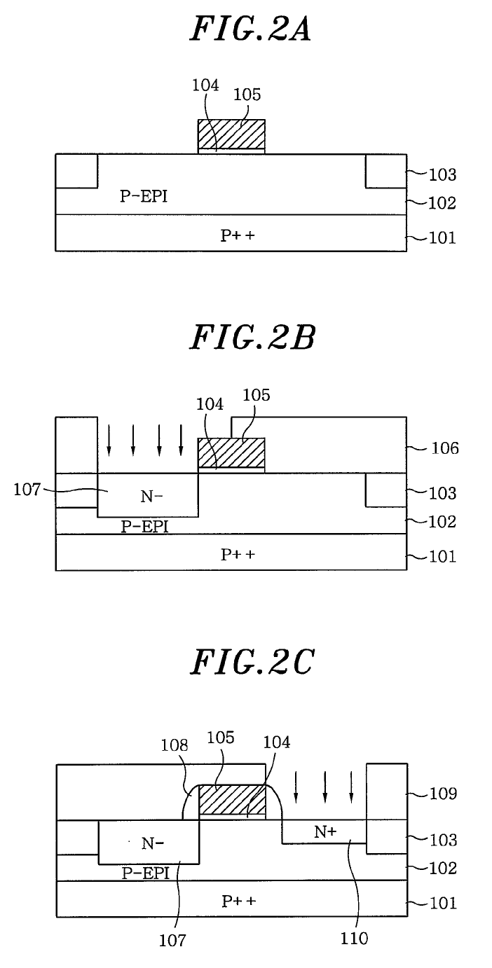

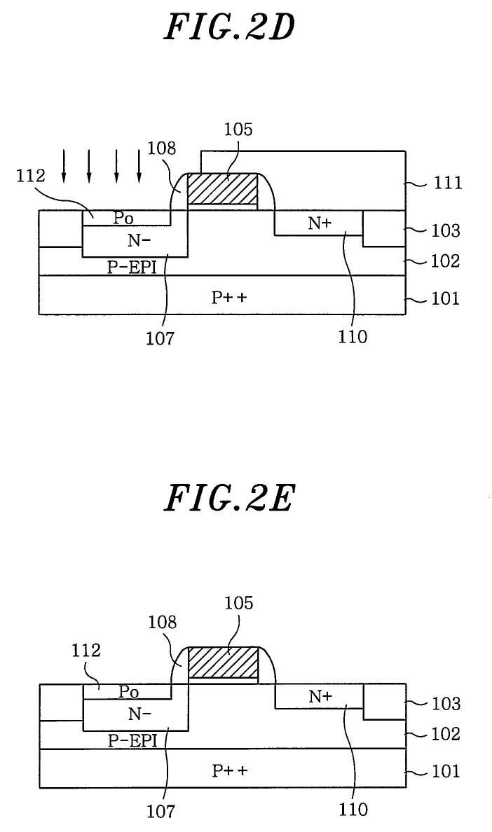

Referring to FIGS. 2A to 2E, there are shown cross-sectional diagrams illustrating a method for fabricating a CMOS image sensor in accordance with the present invention.

As shown in FIG. 2A, a low-concentration P⁻-type epitaxial layer 102 is formed in a semiconductor substrate 101 such as a high-concentration P⁺⁺-type single crystalline silicon, using an epitaxial process.

The epitaxial layer 102 is formed to have a large and deep depletion region in a photodiode, thereby enhancing a capability of a low voltage photodiode to collect light charges and also improving a light sensitivity thereof.

After that, an active region and a device isolation region are defined in the semiconductor substrate 101. A device isolation film 103 is then formed in the device isolation region using Shallow Trench Isolation (STI) process.

A method for forming the device isolation film 103 will be described in the following though not illustrated in the drawings.

First of all, a pad oxide film, a pad nitride film, and a Tetra Ethyl Ortho Silicate (TEOS) oxide film are sequentially formed over the semiconductor substrate 101. A photoresist film is then formed over the TEOS oxide film.

Thereafter, the photoresist film is exposed and patterned using a mask defining the active region and the device isolation region. At this time, the photoresist film of the device isolation region is removed.

The pad oxide film, the pad nitride film, and the TEOS oxide film of the device isolation region are selectively removed with the patterned photoresistt film as a mask.

The semiconductor substrate corresponding to the device isolation region is etched to a predetermined depth with the patterned pad oxide film, pad nitride film, and TEOS oxide film as a mask, thereby forming a trench. The photoresist film is then removed.

Subsequently, insulation material is buried in the trench, thereby forming the device isolation film 103 in the trench. The pad oxide film, the pad nitride film, and the TEOS oxide film are then removed.

A gate insulating film 104 and a conductive layer (e.g., a high-concentration polycrystalline silicon layer) are sequentially deposited on a whole surface of the epitaxial layer 102 including the device isolation film 103.

The gate insulating film 104 may be either formed in a thermal oxidation process or may be formed in a Chemical Vapor Deposition (CVD) method.

The conductive layer and the gate insulating film 104 are selectively removed, thereby forming a gate electrode 105.

The gate electrode 105 becomes a gate electrode of a transfer transistor.

As shown in FIG. 2B, a first photoresist film 106 is coated above a whole surface of the semiconductor substrate 101 including the gate electrode 105 and is patterned to expose each blue, green, and red photodiode region in an exposure and development process.

Next, low-concentration N-type impurity ions are implanted in the epitaxial layer 102 with the patterned first photoresist film 106 as a mask, thereby forming an N⁻-type diffusion region 107 that is the blue, green, and red photo diode region.

When the N⁻-type diffusion region 107 that is the photodiode region is formed, ion implantation of phosphorous (P) is implemented. In order to enhance the efficiency of signal transmission, a series of two processes are performed with different ion implantation energy.

In other words, N-type ion implantation for forming the photodiode region is consecutively performed at different energy of 160 KeV and 100 KeV, respectively. Ion implantation with a low energy is performed at an ion implantation angle of about 4 degrees to 10 degrees. Ion implantation with a great energy is performed at an ion implantation angle of zero degree.

As shown in FIG. 2C, the first photoresist film 106 is all removed. The semiconductor substrate 101 is spike-annealed, thereby compensating for lattice damage to phosphorous ions for forming the N⁻-type diffusion region 107.

In the above process, after the phosphorous ions that are N-type dopants are implanted in the photodiode region, BF₂⁺ ions that are P-type dopants are implanted in an upper part thereof. The ion implantation of phosphorous essentially causes damages on silicon lattices to make an interstitial between the lattices. An amount of the interstitial is proportional to ion implantation amount and energy. A theoretical approach to the diffusion of boron (B) is mainly affected from a Transient Enhanced Diffusion (TED) effect caused by the interstitial between the lattices. Therefore, the interstitial between the lattices is removed before performing the annealing to control the diffusion of P-type dopants at an upper part of the photodiode region.

The condition for the spike annealing is implemented in an N₂ or Ar gas atmosphere below 1000° C., preferably at 800° C. to 900° C. while raising 100° C., to 200° C./sec.

However, because the extent of the interstitial between the lattices is different depending on ion implantation amount and energy of the N-type dopants, the condition may be changed.

The spike annealing is performed at a relative low temperature and is to suppress the diffusion of N-type dopants in the photodiode region and remove only a defect of the interstitial between the lattices. Also, the purpose of the spike annealing is to suppress the diffusion of dopants to the maximum in a previous process of the photodiode region.

Because dopants themselves are not annealed only with the low-temperature spike annealing, a subsequent annealing process should be further performed.

Thereafter, an insulating film is deposited and etched-back above a whole surface of the semiconductor substrate 101. Thus, insulating sidewalls 108 are formed at both side surfaces of the gate electrode 105.

Next, a second photoresist film 109 is coated above a whole surface of the semiconductor substrate 101. The second photoresist film 109 is then patterned to cover the photodiode region and expose a source/drain region of each transistor by an exposure and development process.

High-concentration N⁺-type impurity ions are then implanted in the exposed source/drain region using the patterned second photoresist film 109 as a mask. Thus, an N⁺-type diffusion region (a floated diffusion region) 110 is formed in the exposed source/drain region.

As shown in FIG. 2D, the second photoresist film 109 is removed. After that, a third photoresist film 111 is coated above a whole surface of the semiconductor substrate 101 and is then patterned to expose each photodiode region by an exposure and development process.

Conductive type (P⁰ -type) impurity ions are implanted in the epitaxial layer 102 including the N⁻-type diffusion region 107, using the patterned third photoresist film 111 as a mask. Thus, a P⁰ -type diffusion region 112 is formed in a surface of the epitaxial layer 102.

The impurity ions implanted in the P^{o}-type diffusion region 112 are BF₂ ions. The BF₂ ions are implanted at a concentration of 1×10¹⁶ atoms/cm² to 5×10¹⁷ atoms/cm² and an implantation energy of 5 KeV to 20 KeV.

As shown in FIG. 2E, the third photoresist film 111 is removed. The semiconductor substrate 101 is then heat-treated, thereby promoting diffusion in each impurity diffusion region.

Though subsequent processes are not shown in the drawings, a plurality of metal wirings is formed in an interlayer insulation film at a whole surface of the resultant. After that, a color filter layer and a micro lens are formed. As a result, an image sensor is completed.

Therefore, according to the novel method for fabricating the above-described CMOS image sensor, the photodiode region is formed and spike-annealed to remove the interstitial between the lattices and after that, P-type dopants are implanted in an upper part of the photodiode region, thereby suppressing the diffusion of P-type dopants and thus concurrently improving dark current and sensitivity characteristics of a photodiode.

While the invention has been shown and described with respect to the preferred embodiments, it will be understood by those skilled in the art that various changes and modification may be made without departing from the scope of the invention as defined in the following claims.

What is claimed is:

1. A method for fabricating a Complementary Metal Oxide Semiconductor (CMOS) image sensor, the method comprising the steps of:
implanting first conductive type dopants into a semiconductor substrate and forming a photodiode region in a surface of the semiconductor substrate;
performing spike annealing to the semiconductor substrate having the photodiode region formed thereon; and
implanting second conductive type dopants into an upper part of the photo diode region to form a second conductive type diffusion region.

2. The method of claim 1, wherein the spike annealing is performed in a gas atmosphere below the temperature of 1000° C. while raising 100 to 200° C./sec.

3. The method of claim 2, wherein the spike annealing is preferably performed at 800° C. to 900° C. while raising 100 to 200° C./sec.

4. The method of claim 2, wherein the gas employed in the spike annealing includes N₂.

5. The method of claim 2, wherein the gas employed in the spike annealing includes Ar.

6. The method of claim 1, wherein the step of implanting first conductive type dopants is performed twice with different ion implantation energy.

7. The method of claim 1, further comprising annealing the semiconductor substrate after the forming of the second conductive type diffusion region.

8. The method of claim 1, wherein the spike annealing suppresses diffusion of the first conductive type dopants and remove an interstitial between lattices.
